(19) United States
(12) Patent Application Publication
(10) Pub. No.: US 2003/0188426 A1
(43) Pub. Date: Oct. 9, 2003

(54) Method and system for fabricating and transferring microcircuits

(75) Inventor: W. Edward Naugler JR., Escondido, CA (US)

Correspondence Address: Aldo J. Test, FLEHR HOHBACH TEST, ALBRITTON & HERBERT LLP, Four Embarcadero Center, Suite3400, San Francisco, CA, 94111-4187, US

(73) Assignee: Display Research Laboratories, Inc.

(21) Appl. No.: 10/117,857

(22) Filed: Apr. 5, 2002

(51) Int. Cl. H05K 3/36; H05K 3/20; B23P 19/00

(52) U.S. Cl. 29/831; 29/830; 29/745

(57) ABSTRACT

A method and system for fabricating microcircuits occupying large areas on substrates capable of withstanding high semiconductor processing temperatures and then transferring the circuits onto large substrates incapable of withstanding the high processing temperatures. The method and system is particularly suitable for fabricating large area displays.

### FIELD OF THE INVENTION

The present invention relates generally to a method and system for fabricating and transferring microcircuits, and more particularly to a method of fabricating and processing microcircuits at high temperature on a flexible carrier capable of withstanding the high processing temperature and then transferring the circuits to a substrate such as a transparent plastic.

### BACKGROUND OF THE INVENTION

It is known to fabricate high quality microcircuits, such as TFT circuits, on a silicon substrate which can withstand high processing temperatures, and then to transfer them onto a glass substrate. The microcircuits are adhered to the substrate and then the silicon substrate is removed. The silicon substrate can be removed, for example, by etching the silicon oxide which is formed between the microcircuits and the silicon substrate or by etching away the silicon substrate itself or by thermally shocking the microcircuit and substrate whereby the differential expansion between the circuit and the substrate causes separation. U.S. Pat. Nos. 6,232,136, 6,027,958, 5,702,963, and 5,475,514, among others, describe the above-noted process.

This technology works well for small displays and for transferring a high temperature polysilicon microcircuit from silicon to glass. However, the use of a silicon substrate limits the size of the microcircuit area and is expensive.

There is a need to provide a method in which large area microcircuits can be fabricated and processed at high temperatures to provide high quality, high frequency microcircuits, and then transferred to a substrate such as a transparent flexible plastic. Particularly, there is a need for large area flat panel displays in which the TFT matrixes which drive the liquid crystal displays (LCDs) or light-emitting diodes (LEDs) are formed at elevated temperatures to provide enhanced characteristics and then the circuits are transferred to a transparent panel such as a plastic panel.

### OBJECTS AND SUMMARY OF THE INVENTION

It is a general object of the invention to provide a method in which thin film semiconductor microcircuits are fabricated and processed at high temperatures on a flexible carrier capable of withstanding the high processing temperature and thereafter transferred to a flexible substrate, such as a plastic substrate.

It is another object of the invention to provide a method and system for fabricating high quality thin film transistors (TFTs) at each pixel site of a flat panel display and their high speed drive circuitry.

It is another object of the present invention to provide a method and system which simplifies the fabrication of large area displays and reduces the costs.

In one embodiment of the invention the thin film microcircuitry is fabricated and processed at high temperatures on a high temperature steel foil or belt initially coated with a nickel layer. Once the circuitry has been fabricated on the high temperature foil it is tested and prepared for transfer onto a flexible substrate. The microcircuitry is suitably secured to the flexible substrate and the circuit is thereafter parted from the high temperature substrate by etching away the nickel layer leaving the microcircuit attached to the flexible substrate. The method is particularly suitable for the fabrication of large area flat panel displays and their drive circuits.

### BRIEF DESCRIPTION OF THE DRAWINGS

The invention will be more clearly understood from the following description when read in conjunction with the accompanying drawings in which:

FIG. 1 is a flow diagram of a system for forming or fabricating and transferring microcircuits in accordance with the present invention.

FIG. 2 is an enlarged sectional view of the coated steel belt used in one embodiment of the present invention.

FIG. 3 is an enlarged sectional view of a thin film transistor formed on the steel belt taken along the line 3-3 of FIG. 1.

FIG. 4 is an enlarged sectional view of a flexible transparent substrate taken along the line 4-4 of FIG. 1.

FIG. 5 is an enlarged view of the flexible transparent substrate bound to the microcircuits fabrication on the steel belt taken along the line 5-5 of FIG. 1.

FIG. 6 is an enlarged view of the flexible transparent substrate and mounted microcircuits separated from the steel belt taken along the line 6-6 of FIG. 1.

FIG. 7 is an enlarged view of a thin film transistor mounted on the transparent flexible substrate with an LED applied.

FIG. 8 is a schematic diagram showing the pixels and microcircuits of an LED flat panel display formed in accordance with the present invention.

### DESCRIPTION OF THE PREFERRED EMBODIMENT

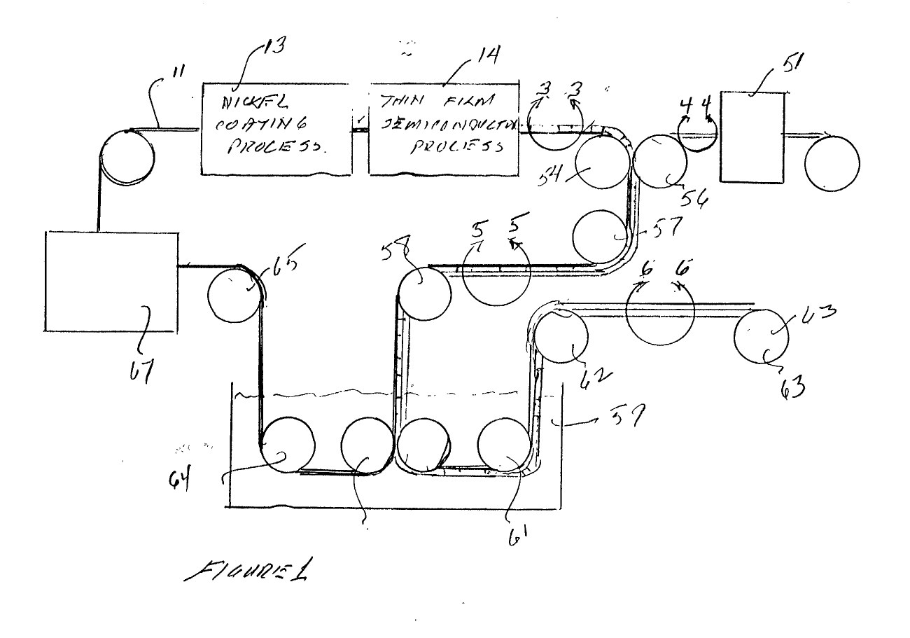

FIG. 1 is a schematic diagram of a system for forming a flexible active matrix back plane ready for the application of light-emitting diodes (LEDs) or organic light-emitting diodes (OLEDs). The flexible active matrix back plane is then further processed to apply the OLED or LED material and the addition of common connection to the LEDs or OLEDs.

In the process illustrated the substrate is a steel belt or foil 11 which can withstand high processing temperatures. Alternatively a high temperature plastic belt such as polymide belt can be used as the substrate when the semiconductor material, such as cadmium selenide, requires lower processing temperatures. In one embodiment, a steel belt 11 is coated with a nickel coating or layer 12 by a process such as electrodeposition or sputtering, step 13. The layer or coating is of a material that can thereafter be dissolved or etched to release the fabricated microcircuits. Alternatively, the layer can be an oxide coating formed by thermal oxidation which likewise can be removed by etching. In order to facilitate the releasing of the microcircuits from the steel belt, the steel belt or alternative belts may have tiny perforations which allow the etching fluid to easily access the release layer. The perforations can be in the order of 0.001 inches in diameter, the fabrication of which is well known in the art. An alternative substrate could be a sintered powder metallurgy substrate which is porous to fluids. This type of metal has been made for years for automobile oil and fuel filters. In the one embodiment, the coated steel belt, FIG. 2, serves as the substrate for the fabrication of thin film microcircuitry on the surface of the belt, step 14. The thin film microcircuitry may for example include TFTs with conductive vertical and horizontal lines for driving the TFTs and exciting the LEDs or OLEDs at each pixel site. TFT drive and control circuits may also be fabricated during this step. The thin film microcircuits may be fabricated by depositing semiconductor material onto the belt and, by techniques well-known in the semiconductor industry, processing the semiconductor material to form TFTs and their interconnections and the drive and control circuits.

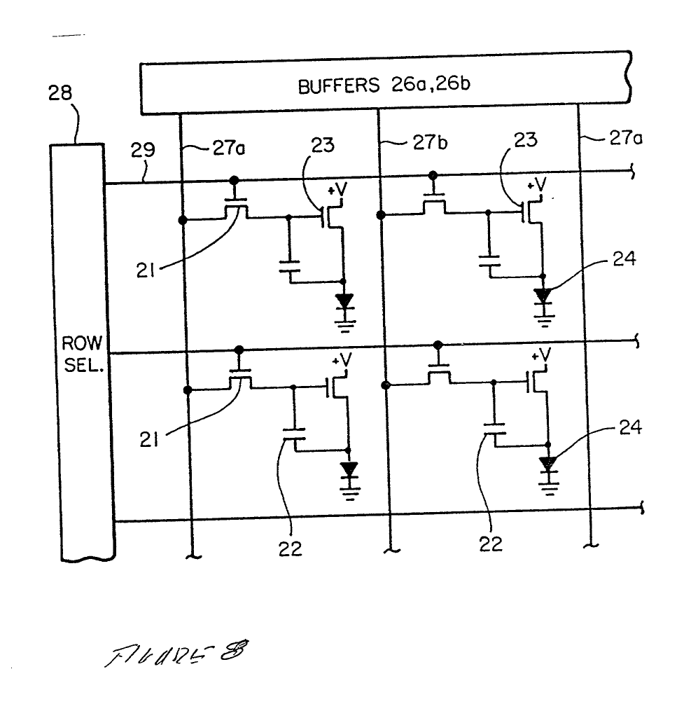

By way of example, the active matrix circuit for the OLED display of FIG. 7 can be fabricated on the steel belt. For an active matrix display, the belt will have a width corresponding to the size of the display so that all elements of the display are fabricated and transferred to the transparent flexible display substrate.

A brief description of the display of FIG. 8 illustrates the type of thin film circuits which can be fabricated in accordance with the present invention. Referring to FIG. 7, each pixel of the active matrix display includes light-emitting diodes 24 driven by a circuit including transmission gates 21, storage capacitors 22 and power FETs 23. The drain of each power FET 23 is connected to the anode of the corresponding light-emitting diode (LED) 24. The cathode of LED 24 is connected to ground. In operation, signal data is stored line by line in buffers 26a and 26b. Buffer 26a feeds signal data to the odd column lines (1, 3, 5, etc.) represented by 27a. Buffer 26b feeds signal data to the even lines (2, 4, 6, etc.), represented by 27b. Which pixel is to receive the data from the buffers is determined by row selector 28. As the signal data arrives at the matrix, first buffer 26 is filled with the first line of the display frame. When the complete first line is in buffer 26, the row selector places a signal on columns 27. This row signal opens all the transmission gates 21 in the first row 29, and the data stored in the buffer 26 is downloaded and stored as a voltage in storage capacitor 22 at each pixel on the selected row. The total storage capacitance is the sum of the metal connection lines, the gate capacitance of output FET 23, and the capacitance of the storage capacitor 22. The storage duration is determined by the RC time constant calculated by the reverse resistance of transmission gate 21, plus the storage capacitance 22, leakage resistance times the total storage capacitance. The storage RC constant should be at least three times the frame duration in time. For example, if the signal data consists of sixty (60) frames per second, the frame duration time is 16.7 ms and the RC constant should be 49.5 ms or greater. Therefore, frame rate plus the total reverse leakage resistance determines the size of the total storage capacitance.

The voltage level +V and duration placed on the gate of output FET 23 determines the perceived brightness of LED 24. this means that there are two ways to effect brightness (gray scale). The first is by storing the value of voltage level of the display voltage on storage capacitor 22. The second way is to break the display frame into eight (8) binary sub-frames that can be combined in 256 ways to give varying time durations of the voltage signal on storage capacitor 22. This is called 8-bit gray scale.

The microcircuitry fabricated in the above-described embodiment of the invention is a combination of active matrix arrays for the LEDs or OLEDs and the row and column drivers for operating the display. Since particularly the row and column drivers require high speed circuitry, high temperature, annealing procedures are required to maximize the electron mobility in the deposited semiconductor material of the microcircuitry. In the case of a polysilicon temperatures as high as 900° are advantageous. Other types of semiconductor thin film, such as CdSe, circuitry may need lower anneal temperatures to maximize the electron mobility.

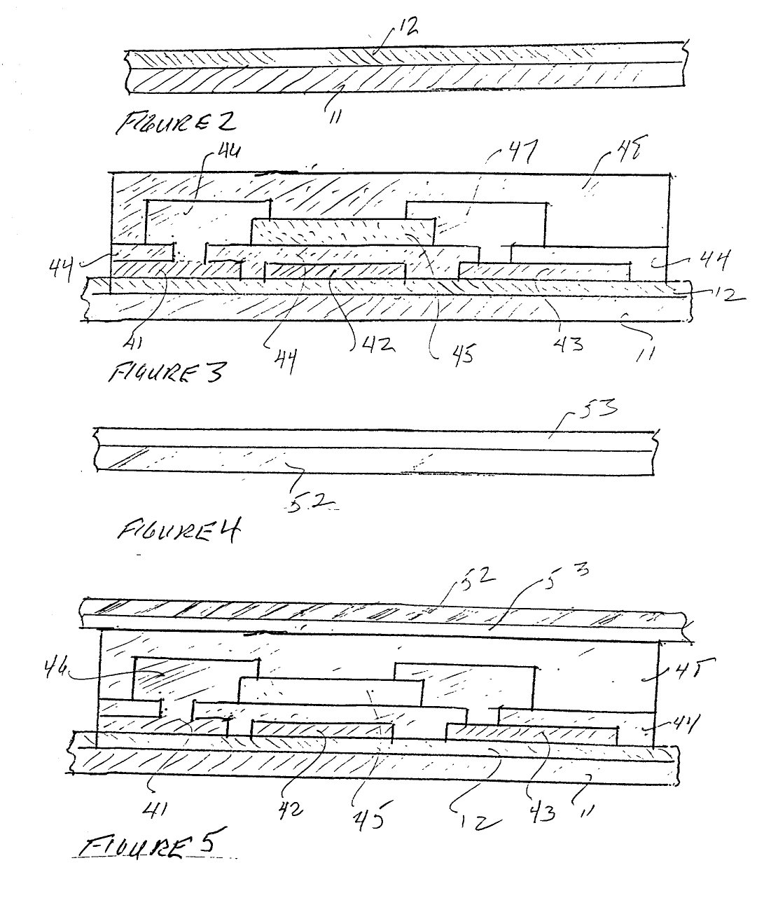

An active matrix pixel drive employing a thin film transistor having an active semiconductor layer is now described with reference to FIGS. 3-6. The thin film transistor is fabricated by depositing the semiconductive material and the metal, and by masking and etching using equipment and techniques well-known in the semiconductor industry for forming the transistor elements. First the drain electrode 41, gate electrode 42 and transparent thin oxide electrode 43 are formed. Thereafter, oxide regions 44 are grown and defined. A semiconductor polysilicon channel material 45 is deposited, defined and subjected to high temperature annealing procedure required to maximize electron mobility. Temperatures as high as 900° C. are advantageous. If semiconductor materials such as cadmium selenide are used, lower annealing temperature are required and the belt can be plastic material such as polymide. Chrome/aluminum source and drain contacts 46 and 47 are then formed and an oxide passivation layer 48 is grown. The foregoing is merely illustrative of a procedure for forming a thin film transistor. It will be apparent that other devices can be formed. The thin film transistors and/or other devices are interconnected by conductive metal lines, not shown, to complete the microcircuit. For example, a flat panel display circuit such as that shown in FIG. 7 can be formed.

Once the microcircuitry is fabricated on the belt, it is tested and prepared for transfer to a transparent flexible substrate or panel.

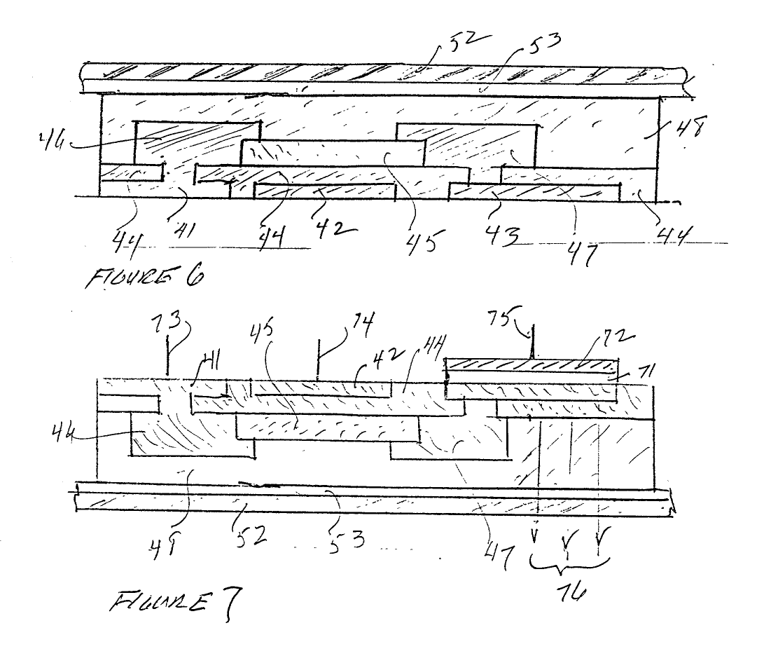

In the next step 51, FIG. 1, the completed microcircuits are adhered to the flexible transparent substrate 52 having a clear epoxy bonding layer 53, FIG. 5. The flexible transparent substrate with the epoxy bonding layer and the steel belt with the microcircuits, FIG. 3, travel between rollers 54 and 56 where they are pressed together and adhered to form a sandwich, FIG. 5. The sandwich is then directed over rollers 57, 58 to an electro-etch bath 59 where the nickel coating is etched away. This allows the steel foil to separate from the transparent flexible substrate or material and microcircuits, FIG. 6. The transparent belt and microcircuits travel over rollers 61, 62 and are, for example, reeled onto a roll 63. The steel substrate travels over rollers 64, 65 to a cleaning bath 67 and is reused. The steel belts can have an oxide separating layer rather than a nickel layer. The oxide layer can be etched with a suitable etchant.

Referring to FIG. 7, a light-emitting diode 71 and metal cathode 72 are then formed on the transparent thin oxide layer 43. Electrodes 73, 74 and 75 are then applied to the drain, gate and cathode, respectively, to excite the light-emitting diode 71 and emit light 76 at each pixel site through the transparent epoxy bonding layer 53 and flexible plastic substrate 52.

Although a continuous process using a belt substrate has been described, it should be apparent that the steel or polymide substrate may be a rigid panel the size of the display. The required microcircuitry can be fabricated on the substrate and transferred to a panel of the same or larger size by pressing. Separation can be by etching.

Thus, there has been provided a system and method for fabricating integrated large-area flat panel displays.

What is claimed is:

1. A system for fabricating large-area microcircuits comprising:
a flexible belt made of a material which can withstand the microcircuit processing temperatures,
means for moving the belt,
a station for receiving the belt and applying a separating layer on one surface of the belt,
a station for receiving the belt and fabricating and processing integrated microcircuits on the separating layer,
a second belt made of a flexible plastic material,
a station for receiving said plastic substrate and applying a bonding layer to one surface,
rollers for continuously moving the belt with fabricated integrated microcircuits into engagement with the bonding layer of the flexible plastic belt whereby the microcircuits are bonded to the flexible plastic belt,
a station for receiving the bonded plastic belt and the belt with the microcircuits and removing the separating layer whereby the microcircuits are transferred to the plastic belt.

2. A system as in claim 1 wherein the belt is steel and the separating layer is nickel.

3. A system as in claim 1 wherein the belt is steel and the separating layer is an oxide.

4. A system as in claim 1 in which the belt is polymide.

5. A system as in claim 1, 2, 3 or 4 wherein the belt is perforated.

6. A system as in claim 1 in which the belt is a sintered powdered metal alloy.

7. A system as in claim 1 in which the microcircuits are fabricated from a high temperature polysilicon material.

8. A system as in claim 1 in which the microcircuits are fabricated from a moderate temperature CdSe semiconductor.

9. A method of fabricating microcircuits for a flat panel display comprising the steps of:
selecting a substrate having the size of the flat panel display capable of withstanding the microcircuit processing temperatures,
applying a separation layer to said substrate,
fabricating the microcircuits on said separation layer, and
transferring the microcircuits onto a transparent display panel.

10. The method of claim 9 wherein the substrate is steel.

11. The method of claim 10 wherein the separation layer is nickel.

12. The method of claim 9 wherein the transparent display panel is plastic.

13. The method of claim 9 wherein the substrate is rigid.

14. The method of claim 9 wherein the substrate is flexible and the panel is flexible.

15. The method of claim 9, 10, 11, 13 or 14 wherein the substrate is perforated.

16. The method of claim 9 wherein the substrate is a sintered powdered metal alloy.
